(19) United States
(12) Patent Application Publication
(10) Pub. No.: US 2020/0091120 A1
(43) Pub. Date: Mar. 19, 2020

(54) SEMICONDUCTOR MODULE, DISPLAY DEVICE, AND SEMICONDUCTOR MODULE MANUFACTURING METHOD

(71) Applicant: SHARP KABUSHIKI KAISHA, Sakai City, Osaka (JP)

(72) Inventor: HIROYOSHI HIGASHISAKA, Sakai City, Osaka (JP)

(73) Assignees: SHARP KABUSHIKI KAISHA, Sakai City, Osaka (JP); SHARP KABUSHIKI KAISHA, Sakai City, Osaka (JP)

(21) Appl. No.: 16/618,062

(22) PCT Filed: Mar. 8, 2018
(86) PCT No.: PCT/JP2018/008909

§ 371 Date: Nov. 27, 2019

(30) Foreign Application Priority Data
May 30, 2017 (JP) 2017-106981

(51) Int. Cl. H01L 25/075; H01L 25/00; H01L 23/00; H01L 23/29; H01L 23/31

(52) U.S. Cl. CPC H01L 25/0753; H01L 25/50; H01L 23/3121; H01L 23/293; H01L 24/45

(57) ABSTRACT

Resin covers a side surface and a back surface of a blue LED and holds the blue LED level. An electrode is disposed between a top surface of a wiring substrate and a back surface of the blue LED, extends through the resin, and electrically connects the wiring substrate and the blue LED to each other. A light-outgoing surface (top-surface) of the blue LED is exposed without being covered with the resin, and the light-outgoing surface (top-surface) is flush with a top surface of the resin.

### TECHNICAL FIELD

The present invention relates to a semiconductor module, a display device, and a semiconductor module manufacturing method.

### BACKGROUND ART

PTLs 1 to 3 disclose examples of existing light-emitting devices.

### CITATION LIST

### Patent Literature

PTL 1: Japanese Unexamined Patent Application Publication No. 2015-126209 (disclosed on Jul. 6, 2015)

PTL 2: Japanese Patent No. 5526782 (registered on Apr. 26, 2014)

PTL 3: Japanese Unexamined Patent Application Publication (Translation of PCT Application) No. 2012-503876 (disclosed on Feb. 9, 2012)

### SUMMARY OF INVENTION

### Technical Problem

Each of the existing light-emitting devices fails to improve the resolution of light-emitting segments.

The present invention is made to solve the above problem, and aims to improve the resolution of light-emitting segments.

### Solution to Problem

To address the above problem, a semiconductor module according to an aspect of the present invention includes a substrate; a light-emitting chip mounted on the substrate; a resin covering a side surface and a back surface of the light-emitting chip and holding the light-emitting chip level; and an electrode member disposed between a top surface of the substrate and the back surface of the light-emitting chip, penetrating through the resin, and electrically connecting the substrate and the light-emitting chip to each other. A light-outgoing surface (top surface) of the light-emitting chip is exposed from the resin. The light-outgoing surface (top surface) and a top surface of the resin are arranged on the same plane.

To address the above problem, a semiconductor module according to another aspect of the present invention includes a substrate; a plurality of light-emitting chips juxtaposed on the substrate; a resin covering side surfaces and back surfaces of the plurality of light-emitting chips and holding the plurality of light-emitting chips level; and an electrode member disposed between a top surface of the substrate and the back surfaces of the plurality of light-emitting chips, penetrating through the resin, and electrically connecting the substrate and the plurality of light-emitting chips to each other. Light-outgoing surfaces (top surfaces) of the plurality of light-emitting chips are exposed from the resin. The light-outgoing surfaces (top surfaces) and a top surface of the resin are arranged on the same plane.

### Advantageous Effects of Invention

An aspect of the present invention has an effect of improving the resolution of light-emitting segments.

### BRIEF DESCRIPTION OF DRAWINGS

FIG. 1 is a cross-sectional view of a cross-sectional structure of a semiconductor module according to a first embodiment of the present invention.

FIG. 2 illustrates a method for manufacturing the semiconductor module according to the first embodiment of the present invention.

FIG. 3 is a cross-sectional view of a cross-sectional structure of a semiconductor module according to a second embodiment of the present invention.

FIG. 4 is a cross-sectional view of a cross-sectional structure of a semiconductor module according to a third embodiment of the present invention.

FIG. 5 is a cross-sectional view of a cross-sectional structure of a semiconductor module according to a fourth embodiment of the present invention.

FIG. 6 illustrates effects exerted by the semiconductor module according to the fourth embodiment of the present invention.

FIG. 7 is a cross-sectional view of a cross-sectional structure of a semiconductor module according to a fifth embodiment of the present invention.

### DESCRIPTION OF EMBODIMENTS

### First Embodiment

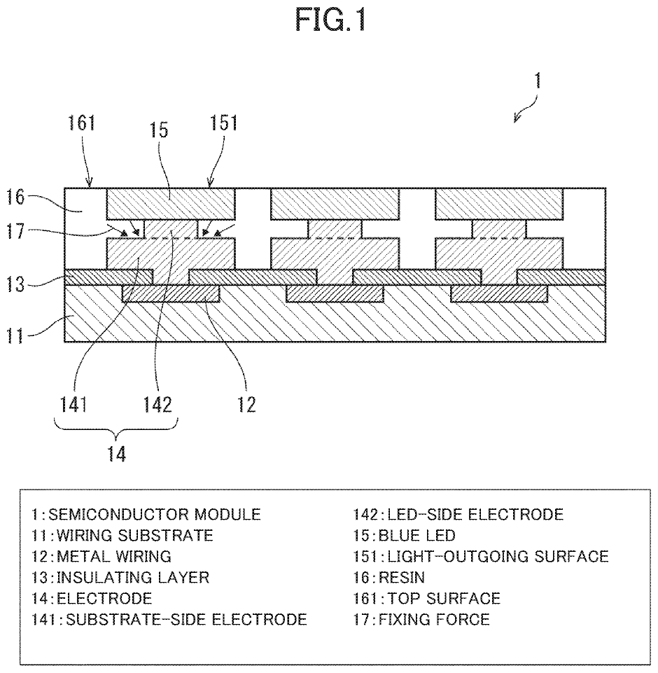

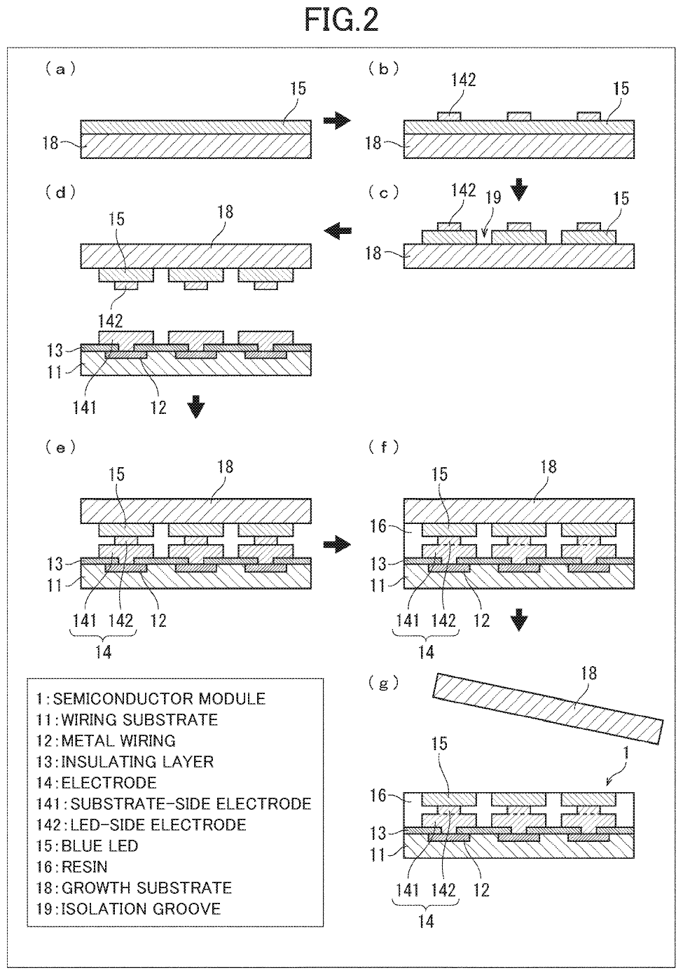

A first embodiment of the present invention will be described below with reference to FIG. 1 and FIG. 2.

### (Structure of Semiconductor Module 1)

FIG. 1 is a cross-sectional view of a cross-sectional structure of a semiconductor module 1 according to a first embodiment of the present invention. As illustrated in this drawing, the semiconductor module 1 includes a wiring substrate 11, a metal wiring 12, an insulating layer 13, electrodes 14, blue LEDs 15, and resin 16.

The semiconductor module 1 is, for example, a light-emitting device installed in a small-sized display device, such as a head mounted display. The semiconductor module 1 includes separate blue LEDs 15 at positions corresponding to pixels of an existing typical display device. The semiconductor module 1 controls turning on and off of the respective blue LEDs 15 to help the display device to display information.

The semiconductor module 1 preferably includes the individual blue LEDs 15 of a small size and has a layout where the blue LEDs 15 are arranged highly densely. This layout can improve the resolution of the display screen. The present technology is applicable to a product including individual blue LEDs 15 having a length and a width of smaller than or equal to 20 μm, more preferably, several micrometers to ten-odd micrometers in a top view.

### (Wiring Substrate 11)

Examples usable as the wiring substrate 11 include a member having at least a top surface formed into a wiring to be connectable to the blue LEDs 15. The materials usable for the wiring substrate 11 include the followings: a crystalline substrate of a single-crystal or polycrystal of an aluminium nitride and a sintered substrate, the entire of which is formed of an aluminium nitride; a ceramic substrate such as alumina; a glass substrate; a semiconductor substrate such as Si; metal substrate; and a layered product or a composite such as a substrate having an aluminium nitride thin film layer disposed on its top surface. A metal substrate and a ceramic substrate have high heat dispersion characteristics, which are preferably usable.

For example, use of a substrate including a circuit for controlling light emission of LEDs formed on Si by an integrated circuit formation technology enables manufacture of a high-resolution display device including densely arranged fine LEDs.

### (Metal Wiring 12)

The metal wiring 12 is a wiring containing at least a control circuit that applies a control voltage to the blue LEDs 15. The metal wiring 12 is formed by patterning a metal layer by, for example, etching. For example, the metal wiring 12 made of Al or Cu or other members are formed on the top surface of a Si substrate. To protect the metal wiring 12, a protective coat made of, for example, a SiO₂ thin film may be formed on the top surface of the substrate on which the metal wiring 12 is formed.

### (Insulating Layer 13)

The insulating layer 13 is an insulating layer formed from an oxide film layer and/or a resin layer. The insulating layer 13 prevents the wiring substrate 11 and the electrode 14 from directly touching each other.

### (Electrode 14)

The electrodes 14 each function as a pad electrode that electrically connects the metal wiring 12 and a metal terminal (not illustrated) on the surface of the corresponding blue LED 15. The electrodes 14 are also referred to as bumps. A first portion of each electrode 14 connected to the metal wiring 12 is a substrate-side electrode 141, whereas a second portion of each electrode 14 connected to the metal terminal (not illustrated) on the surface of the corresponding blue LED 15 is a LED-side electrode 142. The substrate-side electrode 141 and the LED-side electrode 142 are formed from, for example, any metal of Au, Pt, Pd, Rh, Ni, W, Mo, Cr, and Ti, an alloy of any of these, or a combination of any two or more of these. When the substrate-side electrode 141 and the LED-side electrode 142 are formed from metal electrode layers, a conceivable combination example is a laminated structure of, from the bottom surface, W/Pt/Au, Rh/Pt/Au, W/Pt/Au/Ni, Pt/Au, Ti/Pt/Au, Ti/Rh, or TiW/Au.

The electrode 14 has a stepped portion in a light-outgoing direction. The area of a cross section (first area, or cross-sectional area) of the substrate-side electrode 141 taken parallel to the light-outgoing direction is different from the area of a cross section (second area, or cross-sectional area) of the LED-side electrode 142 taken parallel to the light-outgoing direction. In FIG. 1, the cross-sectional area of the substrate-side electrode 141 is greater than the cross-sectional area of the LED-side electrode 142. Preferably, the substrate-side electrode 141 and the LED-side electrode 142 each have an outermost surface made of Au.

### (Blue LEDs 15)

Known devices, specifically, semiconductor light-emitting devices are usable as the blue LEDs 15. A GaN semiconductor is capable of emitting short-wavelength light that can efficiently excite a fluorescent substance, and is thus particularly preferable for the blue LEDs 15.

A nitride semiconductor, capable of emitting light of a short-wavelength range of a visible light range, a near-ultraviolet range, or a shorter wavelength range, is preferably usable as the semiconductor layer of each blue LED 15, in a semiconductor module 1 including a combination of the nitride semiconductor and a wavelength transformation member (fluorescent substance). Instead, for example, a ZnSe, InGaAs, or AlInGaP semiconductor may be used.

A light-emitting device formed from a semiconductor layer preferably has, in terms of output and efficiency, a structure including an active layer between a first electro-conductive (n-type) layer and a second electro-conductive (p-type) layer, but not limited to this. Each electro-conductive layer may partially have an insulating, semi-insulating, or reverse-conducting structure, or this structure may be added to the first and second electro-conductive layers. Another circuit structure, for example, a protective element structure may be additionally provided.

Examples of the structures of each blue LED 15 and their semiconductor layers include a homostructure, a heterostructure, and a double heterostructure including a MIS junction, a PIN junction, or a PN junction. Alternatively, each layer may have a superlattice structure, or a single-quantum well or multiple-quantum well structure in which the light-emitting layer that is an active layer is formed into a thin film that causes a quantum effect.

A metal terminal that enables power feeding from the exterior is disposed on the surface of each blue LED 15.

Although the size of each individual blue LED 15 is not limited to a particular size, when the display screen is required to have high resolution, the blue LEDs 15 are required to be minute having, for example, a length and a width of smaller than or equal to 20 μm, more preferably, smaller than or equal to ten-odd micrometers. The present technology enables stable fixing of each small-sized blue LED 15 onto the wiring substrate 11 with the resin 16 having sufficiently high adhesion.

### (Resin 16)

The resin 16 allows the blue LEDs 15 and the electrodes 14 to be fixed to the wiring substrate 11, and prevents light from leaking through the side surfaces of the blue LEDs 15. The resin 16 is also referred to as underfill, and formed by, for example, curing liquid resin. The resin 16 is filled in an area of the semiconductor module 1, the area including at least an upper portion of the wiring substrate 11, a portion of the side surface of each blue LED 15, and the side surface of each electrode 14.

Light emitted from each blue LED 15 is discharged from the light-outgoing surface 151 of the blue LED 15 opposite to the surface facing the wiring substrate 11. Thus, covering at least the side surface of each blue LED 15 with the resin 16 exerts the following operation and effects. The first is that light is prevented from leaking from the side surface of each blue LED 15. The second is that reduce the color unevenness in the entire luminescent color by preventing a significant amount of light having a color difference from being discharged outward from the side surface, compared with the light emitted from a light-outgoing surface 151. The third is that enhance the directivity of the discharged light and light emission luminance at the light-outgoing surface 151 by reflecting light travelling toward the side surface toward a side of the semiconductor module 1 from which the light is discharged, and restricting the light emission area traveling outward. The fourth is that enhance its thermal dissipation by transmitted heat generated by each blue LED 15 is transmitted to the resin 16. The fifth is that the light-emitting layer of each blue LED 15 can enhance its moistureproofness.

The resin 16 may have any profile as long as it covers the side surface of each blue LED 15 continuous with the light-outgoing surface 151, specifically, the side surface parallel to the thickness direction of each blue LED 15, and the light-outgoing surface 151 is exposed without being covered with the resin 16. For example, the resin 16 may protrude beyond the light-outgoing surface 151 or may be recessed in the light-outgoing surface 151.

As illustrated in FIG. 1, in the first embodiment, the top surface 161 of the resin 16 is flush with the light-outgoing surface 151. Specifically, the exposed surface of the resin 16 in the cover area is substantially flush with the light-outgoing surface 151. This structure reduces variation of the light emission characteristics in the semiconductor module 1, and improves the yield. In addition, covering substantially the entirety of the side surface enhances thermal dissipation of each blue LED 15.

In the present embodiment, the resin 16 is white resin or black resin. Preferably, the resin 16 is colored, and more preferably, white or black.

### (Enhancement of Fixing of Electrode 14)

In FIG. 1, the cross-sectional area of the substrate-side electrode 141 is different from the cross-sectional area of the LED-side electrode 142. Thus, besides the side surface of the substrate-side electrode 141 and the side surface of the LED-side electrode 142, the resin 16 also adheres to an area (stepped surface) where the top surface of any of the electrodes is exposed. An adsorption effect of the resin 16 is exerted on the stepped surface, and thus the substrate-side electrode 141 and the LED-side electrode 142 are more firmly fixed to the wiring substrate 11.

As illustrated in FIG. 1, when the cross-sectional area of the substrate-side electrode 141 is greater than the cross-sectional area of the LED-side electrode 142, a fixing force 17, which presses the substrate-side electrode 141 against the wiring substrate 11 from above the stepped surface of the substrate-side electrode 141, is exerted on the substrate-side electrode 141. Thus, each electrode 14 and the corresponding blue LED 15 disposed on the electrode 14 can be more stably fixed to the wiring substrate 11, which is preferable. The light-outgoing surface 151 of each blue LED 15 and the top surface 161 of the resin 16 are preferably substantially flush with each other. This structure can prevent light emitted from each blue LED 15 from outgoing toward the side surface of the blue LED 15, and thus can enhance the light emission efficiency of the blue LED 15.

### (Method for Manufacturing Semiconductor Module 1)

FIG. 2 illustrates a method for manufacturing the semiconductor module 1 according to the first embodiment of the present invention.

### (Step of Forming Blue LED 15)

As illustrated in FIG. 2(a), firstly, the blue LED 15 is disposed on a growth substrate 18. The growth substrate 18 is a substrate on which the semiconductor layer of the blue LED 15 is epitaxially grown. Examples of the substrate for the nitride semiconductor include the followings: an insulating substrate formed from sapphire or spinel (MgAl₂O₄) having any of a C-plane, R-plane, and A-plane serving as a main surface; an oxide substrate formed from, for example, a lithium niobate or a neodymium gallate that is joined into a lattice with a silicon carbide (6H, 4H, or 3C), Si, ZnS, ZnO, GaAs, diamond, and a nitride semiconductor; and a nitride semiconductor substrate formed from, for example, GaN or AlN.

An example of a nitride semiconductor may include mixed crystal of any two or more of B, P, and As having a general formula of InₓAl_{y}Ga_{1-x-y}N (where 0≤x, 0≤y, and x+y≤1). The n-type semiconductor layer or the p-type semiconductor layer of the blue LED 15 may be formed of either a single layer or multiple layers. The nitride semiconductor layer includes a light-emitting layer that is an active layer, and this active layer has a single-quantum well (SQW) or multiple-quantum well (MQW) structure.

For example, an Si-doped GaN n-type contact layer and an GaN/InGaN n-type multilayer film layer are laminated, as an n-type nitride semiconductor layer, on the growth substrate 18 with a nitride semiconductor undercoat layer such as a buffer layer, or, for example, a low-temperature growing thin film GaN and a GaN layer interposed therebetween. Subsequently, an InGaN/GaN MQW active layer is laminated. Then, for example, a Mg-doped InGaN/AlGaN p-type multilayer film layer and a Mg-doped GaN p-type contact layer are laminated as a p-type nitride semiconductor layer. The light-emitting layer (active layer) of the nitride semiconductor has a quantum well structure including, for example, a well layer, or a barrier layer and a well layer. The nitride semiconductor used as an active layer may be a p-type impurity-doped semiconductor, but preferably, a non-doped or n-type impurity-doped semiconductor to make a high-power light-emitting device.

A well layer containing Al can capture a wavelength shorter than 365 nm, which is a wavelength of the band gap energy of GaN. Light discharged from the active layer preferably has a wavelength of around a range of 360 nm to 650 nm, depending on, for example, the purpose of use of the light-emitting device, or preferably, a wavelength within a range of 380 nm to 560 nm. Among the components of the well layer, InGaN is preferably used for a visible-light/near-ultraviolet range, and the components of the barrier layer suitable for this well layer are GaN and InGaN. Specific examples of film thicknesses of the barrier layer and the well layer are, respectively, greater than or equal to 1 nm and smaller than or equal to 30 nm, and greater than or equal to 1 nm and smaller than or equal to 20 nm. The structure may be a single-quantum well structure including a single well layer or a multiple-quantum well structure including multiple well layers with a barrier layer interposed therebetween.

### (Step of Forming LED-Side Electrode 142)

After the blue LED 15 is formed, as illustrated in FIG. 2(b), multiple LED-side electrodes 142 are formed on the blue LEDs 15. A known, typical electrode forming technology is used for forming the electrodes 142. A typical material for the LED-side electrodes 142 is, for example, Au.

### (Step of Forming Isolation Grooves 19)

After the LED-side electrodes 142 are formed, as illustrated in FIG. 2(c), multiple isolation grooves 19 are formed in the blue LED 15. This formation involves a standard semiconductor selective etching process. In FIG. 2, an isolation groove 19 is formed between each pair of LED-side electrodes 142 adjacent to each other. Each isolation groove 19 thus formed reaches the surface of the growth substrate 18. When the isolation grooves 19 are formed, a single blue LED 15 is split into multiple separate blue LEDs 15 (light-emitting chips) on the surface of the growth substrate 18.

### (Step of Registering Two Substrates)

After the isolation grooves 19 are formed, as illustrated in FIG. 2(d), the wiring substrate 11 on which the metal wiring 12, the insulating layer 13, and the substrate-side electrodes 141 are formed in advance is prepared. To form the substrate-side electrodes 141 on the wiring substrate 11, a known typical electrode forming technology is used. A typical material for the substrate-side electrode 141 is, for example, Au. As illustrated in FIG. 2(d), concurrently with the preparation of the wiring substrate 11, the growth substrate 18 is reversed. After reversing the growth substrate 18, the wiring substrate 11 and the growth substrate 18 are registered so that the substrate-side electrodes 141 and the LED-side electrodes 142 face each other.

### (Step of Bonding Two Substrates)

After the registration is finished, as illustrated in FIG. 2(e), the wiring substrate 11 and the growth substrate 18 are bonded together. At this time, using an existing bonding technique, the wiring substrate 11 and the growth substrate 18 are pressed against each other from above and below to join each substrate-side electrode 141 and the corresponding LED-side electrode 142 to each other. Thus, each substrate-side electrode 141 and the corresponding LED-side electrode 142 are integrated to form the electrode 14.

### (Step of Forming Resin 16)

After the bonding step is finished, a gap between the wiring substrate 11 and the growth substrate 18 is filled with liquid resin 16a. FIG. 2(f) illustrates the state where the gap is filled with the liquid resin 16a. At this time, the bonded assembly may be, for example, immersed in a container filled with the liquid resin 16a. Although not limited to a particular material, preferably, the main material of the liquid resin 16a is, for example, epoxy resin. Instead, the liquid resin 16a may be injected into the gap between the wiring substrate 11 and the blue LEDs 15 with an injection needle, particularly, a microneedle of a size suitable for the gap. Examples of the material of the injection needle include metal and plastics.

In the filling step, the liquid resin 16a is preferably filled under the temperature within a temperature range of 50° C. to 200° C. Thus, the liquid resin 16a is properly filled into the gap. The temperature range more preferably extends from 80° C. to 170° C. Within this range, the resin 16 can be prevented from impairing its characteristics (thermal dissipation or adhesion after curing process, described later). The temperature range further preferably extends from 100° C. to 150° C. Within this range, the liquid resin 16a can be substantially perfectly filled with fewer air bubbles or other defects forming in the gap and without convection, which facilitates manufacturing of the semiconductor module 1.

Particularly, when the individual blue LEDs 15 have a minute size with, for example, a length and a width of smaller than or equal to 20 μm, more preferably, several micrometers to ten-odd micrometers, and a thickness of approximately several micrometers (2 μm to 10 μm), the liquid resin 16a effectively functions as a reinforcing member for enhancing the adhesive force in the steps of substrate detachment and after the detachment. This structure can reduce variation in characteristics of the resin 16 between the products, and facilitate manufacturing of the semiconductor module 1.

As illustrated in FIG. 2(f), the liquid resin 16a filled in the gap is completely enclosed in the gap. Thus, the liquid resin 16a is enclosed by the side surfaces of the blue LEDs 15, the side surfaces and the stepped surfaces of the electrodes 14, and the upper portion of the wiring substrate 11. After the liquid resin 16a is completely filled, the liquid resin 16a is cured. Although the method for curing the liquid resin 16a is not limited to a particular method, the liquid resin 16a may be cured by, for example, being heated or irradiated with ultraviolet rays.

### (Step of Detaching Growth Substrate 18)

After the filling step is finished, as illustrated in FIG. 2(g), the growth substrate 18 is detached. This step involves an existing detachment technique. As an example of an existing way of detachment, a detachment technique using laser beam irradiation is usable. For example, when a transparent substrate made of, for example, sapphire is used as the LED growth substrate and a nitride semiconductor is allowed to grow as a light-emitting device layer, irradiation of a laser beam from the transparent substrate side under regular conditions can reduce damages to the interface between the growth substrate and the crystal growth layer. The growth substrate 18 can be detached by another method, such as wet etching, grinding, or polishing.

The resin 16 allows the electrodes 14 and the blue LEDs 15 to firmly fix to the wiring substrate 11. Thus, the blue LEDs 15 and the electrodes 14 are prevented from being removed together when the growth substrate 18 is detached. After the growth substrate 18 is detached, the light-outgoing surfaces 151 of the blue LEDs 15 and the top surface 161 of the resin 16 are exposed. Thus, the manufacturing of the semiconductor module 1 is finished.

The above manufacturing method is a mere example of a method for manufacturing the semiconductor module 1. Each of the steps described above are performed for facilitating manufacture of the semiconductor module 1, and the steps included in the method for manufacturing the semiconductor module 1 are not limited to these.

The components included in the semiconductor module 1 according to the present embodiment have the following relationship. The resin 16 covers the side surfaces and the back surfaces of the blue LEDs 15, and holds the blue LEDs 15 level. The electrodes 14 are electrode members that are disposed between the top surface of the wiring substrate 11 and the back surfaces of the blue LEDs 15, extend through the resin 16, and electrically connect the wiring substrate 11 and the blue LEDs 15 to each other. The light-outgoing surfaces (top surfaces) 151 of the blue LEDs 15 are exposed without being covered with the resin 16, and the light-outgoing surfaces (top surfaces) 151 are flush with the top surface 161 of the resin 16.

The semiconductor module 1 of the present embodiment has the following effects. The electrodes 14 and the resin 16 can hold the blue LEDs 15 level. The size of the access light-emitting segments can be reduced to the size of the blue LEDs 15, so that the resolution of the light-emitting segments can be improved. The semiconductor module 1 can have a stable optical axis. The blue LEDs 15 (fluorescent substance) can be easily formed.

The components included in the semiconductor module 1 according to the present embodiment have the following relationship. The multiple blue LEDs 15 are arranged side by side on the wiring substrate 11. The resin 16 covers the side surfaces and the back surfaces of the multiple blue LEDs 15, and holds the multiple blue LEDs 15 level. The electrodes 14 are electrode members that are disposed between the top surface of the wiring substrate 11 and the back surfaces of the multiple blue LEDs 15, extend through the resin 16, and electrically connect the wiring substrate 11 and the multiple blue LEDs 15. The light-outgoing surfaces (top surfaces) 151 of the multiple light-emitting chips are exposed without being covered with the resin 16, and the light-outgoing surfaces (top surfaces) 151 are flush with the top surface 161 of the resin 16.

The semiconductor module 1 of the present embodiment has the following effects. The electrodes 14 and the resin 16 can hold all the multiple blue LEDs 15 level. This structure can prevent the light-emitting segments from providing awkwardness to people attributable to tilting of some of the blue LEDs 15. Moreover, the size of the multiple light-emitting segments of the semiconductor module 1 can be reduced to the size of the multiple blue LEDs 15, so that the resolution of the multiple light-emitting segments can be improved. The semiconductor module 1 can have a stable optical axis. The multiple blue LEDs 15 (fluorescent substance) can be easily formed. The optical axes of the multiple light-emitting segments can be prevented from being varied, or light emitted from the semiconductor module 1 can be prevented from flickering.

### Second Embodiment

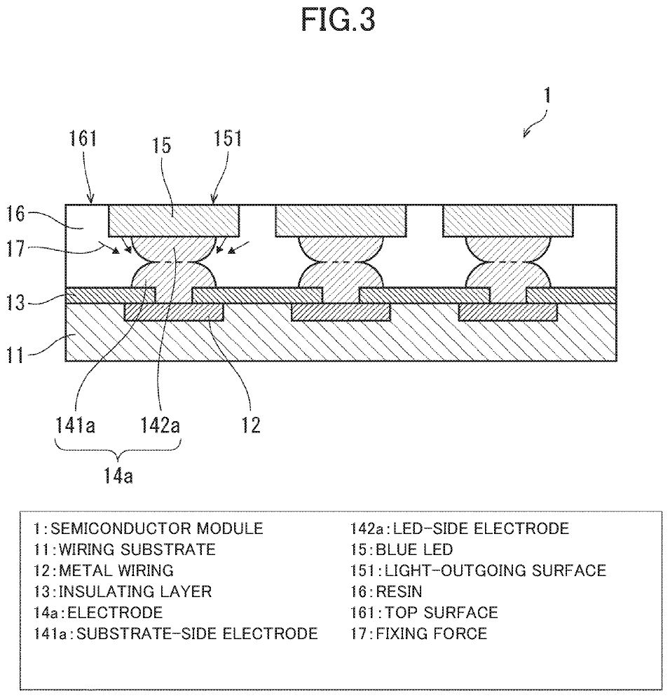

A second embodiment of the present invention will be described below with reference to FIG. 3. In the present embodiment, components that are the same as those of the first embodiment are denoted with the same reference signs without being redundantly described in detail unless particularly needed.

FIG. 3 is a cross-sectional view of a cross-sectional structure of a semiconductor module according to a second embodiment of the present invention. As illustrated in FIG. 3, a semiconductor module 1 according to the present embodiment includes electrodes 14a, instead of the electrodes 14 of the semiconductor module 1 according to the first embodiment. A first portion of each electrode 14a connected to the metal wiring 12 is a substrate-side electrode 141a, and a second portion of the electrode 14a connected to the metal terminal (not illustrated) on the top surface of the corresponding blue LED 15 is a LED-side electrode 142a. The substrate-side electrode 141a and the LED-side electrode 142a have substantially the same size, and have a hemispherical shape. Each electrode 14a has a constricted portion at part of the side surface, and the constricted portion forms a stepped surface.

Assume a case where the wiring substrate 11 and the growth substrate 18 are pressed against each other from above and below to bond the wiring substrate 11 and the growth substrate 18 with each other so that each substrate-side electrode 141a and the corresponding LED-side electrode 142a are joined together. In this case, each substrate-side electrode 141a and the corresponding LED-side electrode 142a are integrated to form the electrode 14a, having the shape illustrated in FIG. 3.

When each substrate-side electrode 141a and the corresponding LED-side electrode 142a are joined together, the resin 16 intrudes into the constricted portion at part of the side surface of the electrode 14a, to enhance the fixing strength between the substrate-side electrode 141a and the LED-side electrode 142a.

The shape of the substrate-side electrode 141a and the LED-side electrode 142a is not limited to a hemispherical shape. The substrate-side electrode 141a and the LED-side electrode 142a may have any shape as long as they form a constricted portion at part of the side surface of the electrode 14a. For example, the substrate-side electrode 141a and the LED-side electrode 142a may have a protruding shape such as a cone or a truncated cone.

### Third Embodiment

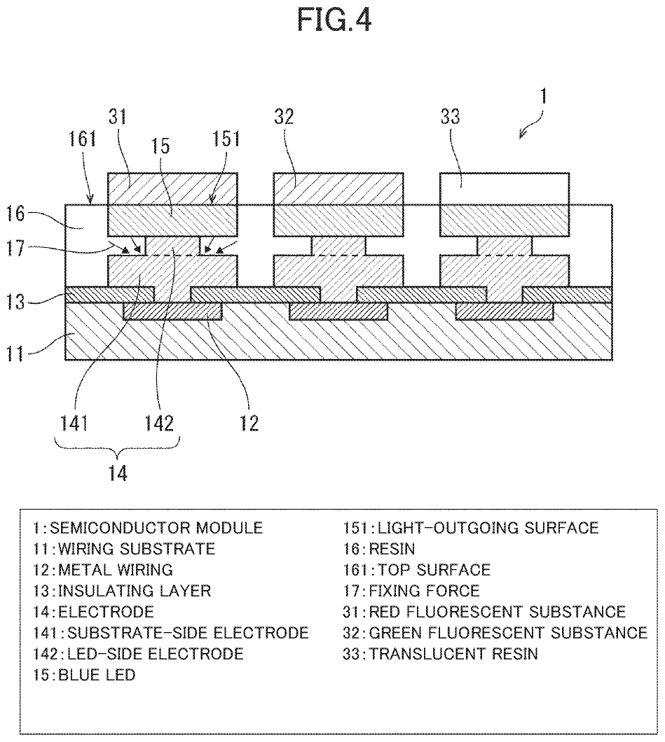

A third embodiment of the present invention will be described below with reference to FIG. 4. Also in the present embodiment, components the same as those of the first and second embodiments are denoted with the same reference signs without being redundantly described in detail unless particularly needed.

FIG. 4 is a cross-sectional view of the cross-sectional structure of a semiconductor module 1 according to a third embodiment of the present invention. As illustrated in FIG. 4, the semiconductor module 1 according to the present embodiment includes a red fluorescent substance 31, a green fluorescent substance 32, and a translucent resin 33 besides all the components of the semiconductor module 1 according to the first embodiment.

The resin 16 is enclosed by the upper portion of the wiring substrate 11, the side surfaces of the blue LEDs 15, and the surroundings of the electrode 14. Three blue LEDs 15 illustrated in FIG. 4 are referred to as first, second, and third blue LEDs 15, below, in order from the left in FIG. 4. The red fluorescent substance 31 is disposed on the top surface (light-outgoing surface 151) of the first blue LED 15. The green fluorescent substance 32 is disposed on the top surface (light-outgoing surface 151) of the second blue LED 15 adjacent to the first blue LED 15. The translucent resin 33 is disposed on the top surface (light-outgoing surface 151) of the third blue LED 15 adjacent to the second blue LED 15. Each fluorescent substance is formed by, for example, photolithography or screen printing to cover at least the light-outgoing surface 151 of the corresponding LED 15.

The red fluorescent substance 31 transforms the wavelength of light emitted from the blue LED 15 disposed immediately below to emit red light. The green fluorescent substance 32 transforms the wavelength of light emitted from the blue LED 15 disposed immediately below to emit green light. The translucent resin 33 allows light emitted from the blue LED 15 disposed immediately below to pass therethrough without transforming the wavelength of the light. The semiconductor module 1 according to the present embodiment can thus emit light of three primary colors, that is, red light, green light, and blue light. A display device into which the semiconductor module 1 according to the present embodiment is installed can thus display color images by controlling light emission of the respective LEDs.

Specific examples of the red fluorescent substance 31 and the green fluorescent substance 32 include the followings: a glass plate and a light-transforming member; any of a sintered body, an aggregate, and a porous material of any of a fluorescent crystal of a light-transforming member, a single crystal, a polycrystal, an amorphous body, a ceramic body, and a fluorescent crystal grain having a fluorescent crystal phase to which a translucent member is added as appropriate; any of the sintered body, the aggregate, and the porous material mixed or impregnated with a translucent member such as resin; and a compact of a translucent member, such as a translucent resin, containing fluorescent particles. An optically transparent member made of an inorganic material rather than an organic material such as resin is preferable from the heat resistance viewpoint. Specifically, the substances are made of a translucent inorganic material containing a fluorescent substance, and particularly, a sintered body of a fluorescent substance and an inorganic substance (binding material), or a sintered body or a single crystal made of a fluorescent substance for enhancing reliability. When an yttrium aluminium garnet (YAG) fluorescent substance is used, a YAG single crystal, a high purity sintered body, or a YAG/alumina sintered body containing alumina (Al₂O₃) as a binding material (binder) is preferable in terms of reliability. Although the red fluorescent substance 31 and the green fluorescent substance 32 may have any shape, the red fluorescent substance 31 and the green fluorescent substance 32 according to the second embodiment have a plate shape. The red fluorescent substance 31 and the green fluorescent substance 32 having a plate shape are highly efficiently coupled with the emerging surfaces of the blue LEDs 15 having a flat shape, and can be easily registered so that the main surfaces of the red fluorescent substance 31 and the green fluorescent substance 32 are substantially parallel to each other. In addition, the red fluorescent substance 31 and the green fluorescent substance 32 each having a substantially uniform thickness can prevent maldistribution of the wavelength transformation member, thus stabilize the rate of color mixture with a substantially uniform amount of transformation of wavelength of light that passes therethrough, and prevent color unevenness at a portion of the light-emitting surface 15a.

Examples of a typical fluorescent substance used as a wavelength transformation member that can emit white light suitably combined with the blue LEDs 15 include a LAG (lutetium aluminium garnet) fluorescent substance and a YAG fluorescent substance activated by cerium. Particularly, for high luminance and long time use, for example, (Re₁₋ₓSmₓ)₃(Al_{1-y}Ga_{y})₅O₁₂:Ce (where 0≤x<1, 0≤y≤1, and Re is at least one element selected from the group consisting of Y, Gd, La, and Lu) is preferable. A fluorescent substance containing any one selected from the group consisting of YAG, LAG, BAM, BAM:Mn, (Zn, Cd) Zn:Cu, CCA, SCA, SCESN, SESN, CESN, CASBN, and CaAlSiN₃:Eu is usable.

In the semiconductor module 1 according to the present embodiment, at least the light-outgoing surface 151 is flat. Thus, the red fluorescent substance 31, the green fluorescent substance 32, and the translucent resin 33 can adhere to the light-outgoing surfaces 151 of the blue LEDs 15 with higher adhesion, and improve their optical characteristics with a uniform thickness. When the top surface 161 of the resin 16 is flush with the light-outgoing surface 151, that is, when the exposed surface of the resin 16 in the cover area is substantially flush with the light-outgoing surface 151, this surface is nearly flat. This structure thus enables stable patterning in the step of forming the fluorescent substances (such as photolithography or screen printing), and thus, the product quality can be expectedly improved.

### Fourth Embodiment

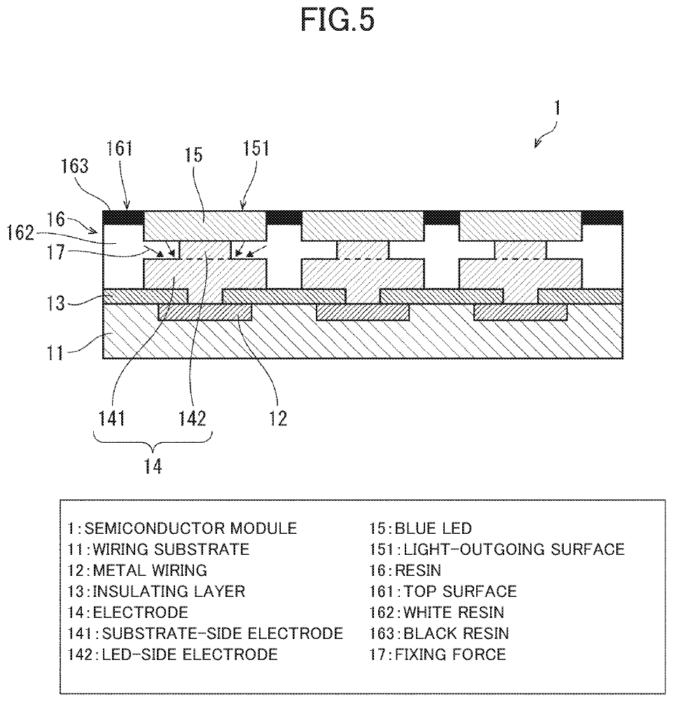

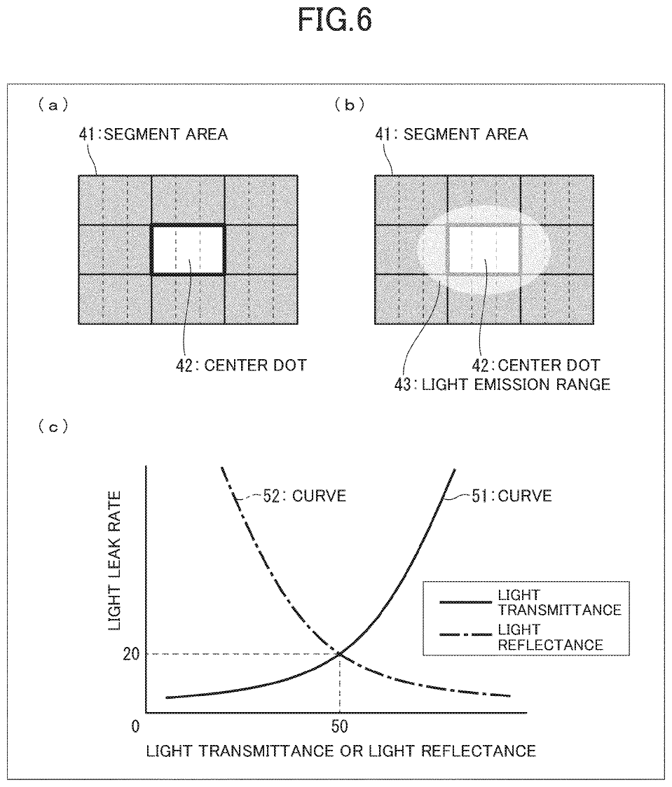

A fourth embodiment of the present invention will be described below with reference to FIGS. 5 and 6. In the present embodiment, components the same as those of at least any one of the first to third embodiments are denoted with the same reference signs without being redundantly described in detail unless particularly needed.

FIG. 5 is a cross-sectional view of a cross-sectional structure of the semiconductor module 1 according to the fourth embodiment of the present invention. As illustrated in FIG. 5, components of the semiconductor module 1 according to the present embodiment are the same as the components of the semiconductor module 1 according to the first embodiment. However, the resin 16 has a different structure in the present embodiment. Specifically, the resin 16 includes at least two layers including a first layer and a second layer. In the example in FIG. 5, the first layer is a white resin 162 (first resin), and the second layer is a black resin 163 (second resin) having lower light reflectance than the white resin 162. The white resin 162 is disposed closer to the wiring substrate 11, and the black resin 163 is disposed on the white resin 162.

In the structure in FIG. 5, the light reflectance of the resin 16 on the surface facing the wiring substrate 11 can be controlled to be greater than or equal to 50%. In addition, the light transmittance of the resin 16 on the surface facing the blue LEDs 15 can be controlled to be smaller than or equal to 50%. The light transmittance and light reflectance of the semiconductor module 1 will be described in detail later.

FIG. 6 illustrates the effects exerted by the semiconductor module 1 according to the fourth embodiment of the present invention.

FIG. 6(a) illustrates multiple segment areas 41 constituting the front surface (top surface) of the semiconductor module 1. FIG. 6(a) illustrates 3×3=9 segment areas 41. One segment area 41 corresponds to, for example, one pixel in the display device in which the semiconductor module 1 is installed. In FIG. 6(a), one segment area 41 is constituted of three dots. Each dot is a portion that emits light of any of, for example, three primary colors.

In FIG. 6(a), when, of the three dots in the center segment area 41, only a center dot 42 at the center of the area emits light, only the center segment area 41 emits light. The light emission luminance here is defined as 100. FIG. 6(b) illustrates the state where light leaks in the semiconductor module 1. In FIG. 6(b), when only the center dot 42 emits light, a light emission range 43 extends from the center segment area 41 to the surrounding segment areas 41. When the light emission luminance in the center segment area 41 is defined as 100, the light emission luminance of light that has leaked to the surrounding segment areas 41 is 20. The light leak rate here is defined as 20%. The light leak rate can be also referred to as a contrast ratio during surface emission of the semiconductor module 1.

FIG. 6(c) shows a graph of the relationship between the light leak rate of the semiconductor module 1 in an in-plane direction and the light transmittance or light reflectance of the resin 16. The vertical axis in this graph represents the light leak rate, and the horizontal axis in this graph represents the light transmittance or light reflectance.

As indicated with a curve 51, the light leak rate of the semiconductor module 1 increases further as the light transmittance of the resin 16 increases further. On the other hand, as indicated with a curve 52, the light leak rate of the semiconductor module 1 decreases further as the light reflectance of the resin 16 increases further. When the light transmittance is smaller than or equal to 50%, the light leak rate is smaller than or equal to 20%. Also when the light reflectance is greater than or equal to 50%, the light leak rate is smaller than or equal to 20%.

In the semiconductor module 1, the light transmittance of the resin 16 is preferably smaller than or equal to 50%. Thus, the light leak rate can be smaller than or equal to 20%. The display quality of the display device in which the semiconductor module 1 is installed can thus be improved. In the semiconductor module 1, the light reflectance of the resin 16 is preferably greater than or equal to 50%. Thus, the light leak rate can be smaller than or equal to 20%, so that the display quality of the display device in which the semiconductor module 1 is installed can be improved.

### Fifth Embodiment

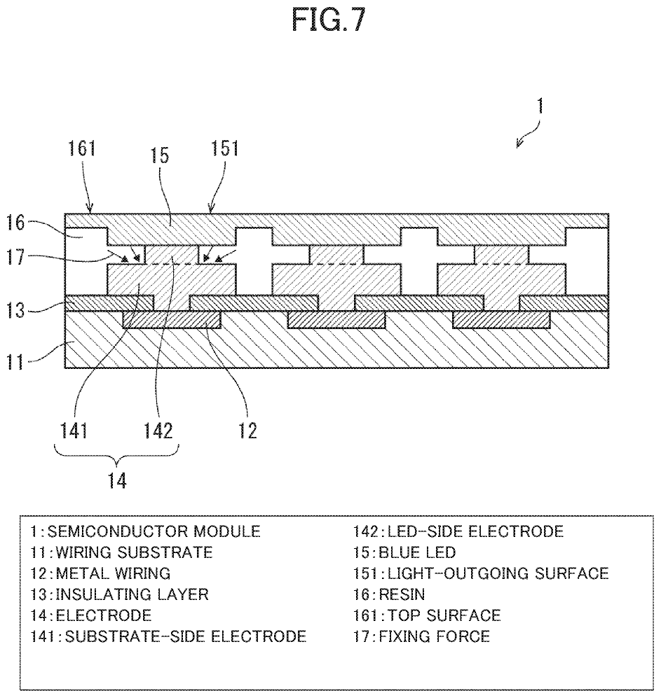

A fourth embodiment of the present invention will be described below with reference to FIG. 7. In the present embodiment, components the same as those of at least one of the first to third embodiments are denoted with the same reference signs without being redundantly described in detail unless particularly needed.

FIG. 7 is a cross-sectional view of the cross-sectional structure of a semiconductor module 1 of a fifth embodiment of the present invention. As illustrated in FIG. 7, components of the semiconductor module 1 according to the present embodiment are the same as the components of the semiconductor module 1 according to the first embodiment. However, the blue LEDs 15 have a different shape in the present embodiment. More specifically, two of the multiple blue LEDs 15 adjacent to each other are at least partially connected to each other at the light-outgoing surface 151. In the example in FIG. 7, the multiple blue LEDs 15 share one light-outgoing surface 151 in common. Thus, the semiconductor module 1 can have a flatter top surface.

The semiconductor module 1 according to the present embodiment is, for example, manufactured as follows. In the step of forming the isolation grooves 19, the isolation grooves 19 are formed without reaching the growth substrate 18 to slightly leave an epitaxial layer (by, for example, 1 μm) on the growth substrate 18. This structure allows, in the detachment step of the growth substrate 18 while, for example, the growth substrate 18 is detached with laser irradiation, a thin layer to be left on the semiconductor module 1 as illustrated in FIG. 7 without breaking a GaN layer not serving as an interface. Thus, the top surface of the semiconductor module 1 during the manufacture can be further flattened.

### SUMMARY

A semiconductor module (1) according to a first aspect of the present invention includes a substrate (wiring substrate 11); a light-emitting chip (blue LED 15) mounted on the substrate; a resin (16) covering a side surface and a back surface of the light-emitting chip and holding the light-emitting chip level; and an electrode member (electrode 14) disposed between a top surface of the substrate and the back surface of the light-emitting chip, penetrating through the resin, and electrically connecting the substrate and the light-emitting chip to each other. A light-outgoing surface (top surface) (151) of the light-emitting chip is exposed from the resin. The light-outgoing surface (top surface) and a top surface (161) of the resin are arranged on the same plan.

In the above structure, the electrode member and the resin can hold the light-emitting chips level. In addition, the size of the light-emitting segment of the semiconductor module can be reduced to the size of the light-emitting chip, so that the resolution of the light-emitting segments can be improved.

A semiconductor module (1) according to a second aspect of the present invention includes a substrate (wiring substrate 11); a plurality of light-emitting chips (blue LEDs 15) juxtaposed on the substrate; a resin (16) covering side surfaces and back surfaces of the plurality of light-emitting chips and holding the plurality of light-emitting chips level; and an electrode member (electrode 14) disposed between a top surface of the substrate and the back surfaces of the plurality of light-emitting chips, penetrating through the resin, and electrically connecting the substrate and the plurality of light-emitting chips to each other. Light-outgoing surfaces (top surfaces) (151) of the plurality of light-emitting chips are exposed from the resin. The light-outgoing surfaces (top surfaces) and a top surface (161) of the resin are arranged on the same plane.

In the above structure, the electrode member and the resin can hold all the multiple light-emitting chips level. This structure can prevent the light-emitting segments from providing awkwardness to people attributable to tilting of some of the light-emitting chips. Moreover, the size of the multiple light-emitting segments of the semiconductor module can be reduced to the size of the multiple light-emitting chips, so that the resolution of the multiple light-emitting segments can be improved.

A semiconductor module according to a third aspect of the present invention depends on the first or second aspect, wherein, in a top view, the light-emitting chip has a length and a width of smaller than or equal to 20 μm.

A semiconductor module according to a fourth aspect of the present invention depends on the first or second aspect, wherein the substrate includes a metal wiring, wherein the electrode member includes a first portion (substrate-side electrode 141) connected to the metal wiring, and a second portion (LED-side electrode 142) connected to the light-emitting chip, and wherein a first area of a cross section of the first portion taken parallel to a light-outgoing direction is different from a second area of a cross section of the second portion taken parallel to the light-outgoing direction.

A semiconductor module according to a fifth aspect of the present invention depends on the fourth aspect, wherein the first area is greater than the second area.

In the above structure, a fixing force that presses the second portion of the electrode against the substrate is exerted on the electrode. Thus, the light-emitting chips can be more firmly fixed to the substrate.

A semiconductor module according to a sixth aspect of the present invention depends on the first or second aspect, wherein the resin includes at least two layers including a first layer and a second layer, and wherein the first layer is a first resin (white resin 162) disposed on the substrate side, and the second layer is a second resin (black resin 163) disposed on the first resin and having lower light reflectance than the first resin.

In the above structure, light is prevented from leaking to the surroundings of the light-emitting chips.

A display device according to a seventh aspect of the present invention includes the semiconductor module according to any one of the first to sixth aspects.

A manufacturing method according to an eighth aspect of the present invention is a method for manufacturing the semiconductor module according to any one of the first to sixth aspects, and includes a step of filling resin in a liquid phase in between substrates under a temperature range from 50° C. to 200° C. before the resin being cured.

In the above structure, a liquid resin can be more easily and properly filled into a gap between the substrates.

A manufacturing method according to a ninth aspect of the present invention depends on the eighth aspect, wherein the temperature range is from 80° C. to 170° C.

In the above structure, cured resin can be prevented from impairing its characteristics (such as adhesion or thermal dissipation).

A manufacturing method according to a tenth aspect of the present invention depends on the eighth aspect, wherein the temperature range is from 100° C. to 150° C.

This structure can reduce variation in characteristics of the cured resin between the products, and facilitate manufacturing of the semiconductor module.

A manufacturing method according to an eleventh aspect of the present invention depends on any one of the eighth to tenth aspects, wherein the semiconductor module includes a substrate including a metal wiring, an electrode disposed on the substrate and connected to the metal wiring, light-emitting devices disposed on the electrode and each including a light-outgoing surface facing away from the substrate, and a resin covering at least the substrate, a part of a side surface of each of the light-emitting devices, and a stepped portion of the electrode. At least portions of the light-emitting devices adjacent to each other are connected to each other on light-outgoing surface sides of the light-emitting devices.

In the above structure, the semiconductor module can have a flatter top surface.

A semiconductor module according to a twelfth aspect of the present invention includes a substrate (wiring substrate 11) including a metal wiring (12), an electrode (14) disposed on the substrate and connected to the metal wiring, and light-emitting devices (blue LEDs 15) disposed on the electrode and each including a light-outgoing surface facing away from the substrate. The electrode includes a stepped portion on a side surface of the electrode. The semiconductor module further includes resin (resin 16) covering at least the substrate, part of a side surface of each of the light-emitting devices, and the stepped portion.

In the above structure, the light-emitting devices and the electrodes can be more firmly fixed to the substrate on which they are mounted.

A semiconductor module according to a 13th aspect of the present invention depends on the twelfth aspect, wherein the light-outgoing surface of each of the light-emitting devices is flush with a top surface of the resin.

In the above structure, light emitted from the light-emitting devices is prevented from emerging from the side surfaces of the light-emitting devices. Thus, the light-emitting devices can improve the light emission efficiency.

A semiconductor module according to a 14th aspect of the present invention includes a substrate including a metal wiring, an electrode disposed on the substrate and connected to the metal wiring, light-emitting devices disposed on the electrode and each including a light-outgoing surface facing away from the substrate, and resin covering at least the substrate, part of a side surface of each of the light-emitting devices, and a stepped portion of the electrode. At least portions of the light-emitting devices adjacent to each other are connected to each other on light-outgoing surface sides of the light-emitting devices.

In the above structure, the semiconductor module can have a flatter top surface.

The present invention is not limited to the above-described embodiments, and may be changed in various manners within the scope of Claims. Embodiments obtained by appropriately combining techniques disclosed in different embodiments are also included in the technical scope of the present invention. Combining the techniques disclosed in the embodiments can form new technical features.

### REFERENCE SIGNS LIST

1 semiconductor module
11 wiring substrate
12 metal wiring
13 insulating layer
14 electrode
15a light-emitting surface
16 resin
17 fixing force
18 growth substrate
19 isolation groove
31 red fluorescent substance
32 green fluorescent substance
33 translucent resin
41 segment area
42 center dot
43 light emission range
51 curve
141 substrate-side electrode (first portion)
142 LED-side electrode (second portion)
151 light-outgoing surface
161 top surface
162 white resin
163 black resin

1. A semiconductor module, comprising:
a substrate;
a light-emitting chip mounted on the substrate;
a resin covering a side surface and a back surface of the light-emitting chip and holding the light-emitting chip level; and
an electrode member disposed between a top surface of the substrate and the back surface of the light-emitting chip, penetrating through the resin, and electrically connecting the substrate and the light-emitting chip to each other,
wherein a light-emerging surface (top surface) of the light-emitting chip is exposed from the resin, and
wherein the light-emerging surface (top surface) and a top surface of the resin are arranged on the same plane.

2. A semiconductor module, comprising:
a substrate;
a plurality of light-emitting chips juxtaposed on the substrate;
a resin covering side surfaces and back surfaces of the plurality of light-emitting chips and holding the plurality of light-emitting chips level; and
an electrode members disposed between a top surface of the substrate and the back surfaces of the plurality of light-emitting chips, respectively, penetrating through the resin, and electrically connecting the substrate and the plurality of light-emitting chips to each other,
wherein light-outgoing surfaces (top surfaces) of the plurality of light-emitting chips are exposed from the resin, and
wherein the light-outgoing surfaces (top surfaces) and a top surface of the resin are arranged on the same plane.

3. The semiconductor module according to claim 1, wherein, in a top view, the light-emitting chip has a length and a width of smaller than or equal to 20 μm.

4. The semiconductor module according to claim 1,
wherein the substrate includes a metal wiring,
wherein the electrode member includes
a first portion connected to the metal wiring, and
a second portion connected to the light-emitting chip, and
wherein a first area of a cross section of the first portion taken parallel to a light-outgoing direction is different from a second area of a cross section of the second portion taken parallel to the light-outgoing direction.

5. The semiconductor module according to claim 4, wherein the first area is greater than the second area.

6. The semiconductor module according to claim 1,
wherein the resin includes at least two layers including a first layer and a second layer, and
wherein the first layer is a first resin disposed on the substrate side, and the second layer is a second resin disposed on the first resin and having lower light reflectance than the first resin.

7. A display device, comprising the semiconductor module according to claim 1.

8. A manufacturing method for manufacturing the semiconductor module according to claim 1, the method comprising:
a step of filling resin in a liquid phase in between substrates under a temperature range from 50° C. to 200° C. before the resin being cured.

9. The manufacturing method according to claim 8, wherein the temperature range is from 80° C. to 170° C.

10. The manufacturing method according to claim 8, wherein the temperature range is from 100° C. to 150° C.

11. The manufacturing method according to claim 8,
wherein the semiconductor module includes
a substrate including a metal wiring,
an electrode disposed on the substrate and connected to the metal wiring,
light-emitting devices disposed on the electrode and each including a light-outgoing surface facing away from the substrate, and
a resin covering at least the substrate, a part of a side surface of each of the light-emitting devices, and a stepped portion of the electrode, and
wherein at least portions of the light-emitting devices adjacent to each other are connected to each other on light-outgoing surface sides of the light-emitting devices.

12. The semiconductor module according to claim 2, wherein, in a top view, the light-emitting chip has a length and a width of smaller than or equal to 20 μm.

13. The semiconductor module according to claim 2,
wherein the substrate includes a metal wiring,
wherein the electrode member includes
a first portion connected to the metal wiring, and
a second portion connected to the light-emitting chip, and
wherein a first area of a cross section of the first portion taken parallel to a light-outgoing direction is different from a second area of a cross section of the second portion taken parallel to the light-outgoing direction.

14. The semiconductor module according to claim 13, wherein the first area is greater than the second area.

15. The semiconductor module according to claim 2,
wherein the resin includes at least two layers including a first layer and a second layer, and
wherein the first layer is a first resin disposed on the substrate side, and the second layer is a second resin disposed on the first resin and having lower light reflectance than the first resin.

16. A display device, comprising the semiconductor module according to claim 2.

17. A manufacturing method for manufacturing the semiconductor module according to claim 2, the method comprising:
a step of filling resin in a liquid phase in between substrates under a temperature range from 50° C. to 200° C. before the resin being cured.

18. The manufacturing method according to claim 17, wherein the temperature range is from 80° C. to 170° C.

19. The manufacturing method according to claim 17, wherein the temperature range is from 100° C. to 150° C.

20. The manufacturing method according to claim 17,
wherein the semiconductor module includes
a substrate including a metal wiring,
an electrode disposed on the substrate and connected to the metal wiring,
light-emitting devices disposed on the electrode and each including a light-outgoing surface facing away from the substrate, and
a resin covering at least the substrate, a part of a side surface of each of the light-emitting devices, and a stepped portion of the electrode, and
wherein at least portions of the light-emitting devices adjacent to each other are connected to each other on light-outgoing surface sides of the light-emitting devices.
